(19) United States
(12) Patent Application Publication
(10) Pub. No.: US 2011/0023947 A1
(43) Pub. Date: Feb. 3, 2011

(54) Dye-sensitized solar cell electrode and dye-sensitized solar cell

(75) Inventors: Shinichi Inoue, Osaka (JP); Hiroyuki Hanazono, Osaka (JP); Takami Hikita, Osaka (JP)

Correspondence Address: AKERMAN SENTERFITT, 8100 BOONE BOULEVARD, SUITE 700, VIENNA, VA, 22182-2683, US

(73) Assignee: Nitto Denko Corporation, Osaka (JP)

(21) Appl. No.: 12/801,882

(22) Filed: Jun. 30, 2010

(30) Foreign Application Priority Data
Jul. 30, 2009 (JP) 2009-178082

(51) Int. Cl. H01L 31/02

(52) U.S. Cl. 136/252

(57) ABSTRACT

A dye-sensitized solar cell electrode includes a substrate composed of a flexible film formed from a liquid crystal polymer.

### CROSS-REFERENCE TO RELATED APPLICATION

The present application claims priority from Japanese Patent Application No. 2009-178082 filed on Jul. 30, 2009, the content of which is hereby incorporated by reference into this application.

### BACKGROUND OF THE INVENTION

1. Field of the Invention

The present invention relates to a dye-sensitized solar cell electrode and a dye-sensitized solar cell. To be specific, the present invention relates to a dye-sensitized solar cell electrode that is suitably used for a counter electrode of a dye-sensitized solar cell, and to a dye-sensitized solar cell in which the dye-sensitized solar cell electrode is used.

2. Description of the Related Art

In recent years, a dye-sensitized solar cell in which a dye-sensitized semiconductor is used has been proposed as a new solar cell that may replace silicon-based solar cells in view of mass production and cost reduction.

A dye-sensitized solar cell usually has a working electrode (anode) having a photosensitizing function, an opposing electrode (counter electrode, cathode) that is disposed to face the working electrode with a space therebetween, and a liquid electrolyte that fills in between the two electrodes. In dye-sensitized solar cells, electrons generated in the working electrode based on irradiation by sunlight migrate to the counter electrode via wirings, and the electrons are given and received in the liquid electrolyte between the two electrodes.

In such dye-sensitized solar cells, the working electrode is composed of a substrate (anode-side substrate), a transparent conductive film that is laminated onto the surface of the substrate, and a dye-sensitized semiconductor that is laminated onto the surface of the conductive film and to which dyes are adsorbed; and the opposing electrode is composed of a substrate (cathode-side substrate), a conductive film that is laminated onto the surface of the substrate, and a catalyst layer laminated onto the surface of the conductive film. The substrates of the working electrode and the counter electrode are usually formed from glass. The liquid electrolyte contains iodine.

There has been proposed that the substrates of those electrodes be formed from resin in dye-sensitized solar cells in order to achieve flexibility and a lightweight. For example, there has been proposed that the substrate of the counter electrode be formed from polyethylene-2,6-naphthalate (PEN) (for example, see Japanese Unexamined Patent Publication No. 2006-282970).

### SUMMARY OF THE INVENTION

However, in the dye-sensitized solar cell disclosed in Japanese Unexamined Patent Publication No. 2006-282970, iodine easily penetrates into the substrate under a high temperature, and therefore physical properties of the substrate are reduced, and appearance of the substrate becomes poor. As a result, disadvantages of a decrease in power generation efficiency of the dye-sensitized solar cell arise.

Additionally, it is necessary that decomposition due to iodine in the liquid electrolyte under a high temperature be prevented in the substrate of a dye-sensitized solar cell.

An object of the present invention is to provide a dye-sensitized solar cell electrode and a dye-sensitized solar cell that can prevent a decrease in power generation efficiency by preventing liquid electrolyte penetration and decomposition due to liquid electrolyte, while achieving mass production and cost reduction by ensuring flexibility and a lightweight.

To achieve the above object, a dye-sensitized solar cell electrode of the present invention includes a substrate composed of a flexible film formed from a liquid crystal polymer.

It is preferable that, in the dye-sensitized solar cell electrode of the present invention, the liquid crystal polymer is at least one para-hydroxybenzoic acid ester-containing copolymer selected from the group consisting of a copolymer containing a unit a and a unit b represented by the following formula (1); a copolymer containing a unit c to a unit e represented by the following formula (2); and a copolymer containing a unit f and a unit g represented by the following formula (3).

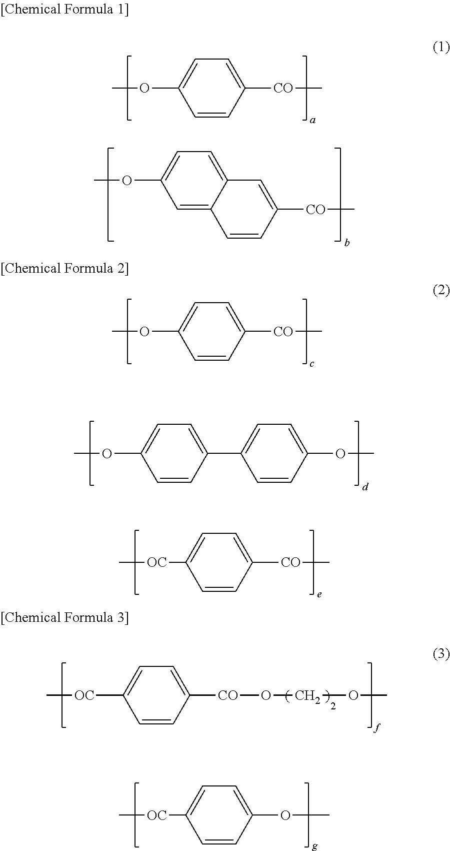

It is preferable that the dye-sensitized solar cell electrode of the present invention further includes a conductive layer formed on the substrate.

It is preferable that in the dye-sensitized solar cell electrode of the present invention, the conductive layer is formed from at least one selected from the group consisting of gold, silver, copper, platinum, nickel, tin, tin doped indium oxide, fluorine-doped tin oxide, and carbon.

It is preferable that in the dye-sensitized solar cell electrode of the present invention, the conductive layer also serves as a catalyst layer, and is formed from carbon.

It is preferable that the dye-sensitized solar cell electrode of the present invention further includes a catalyst layer formed on the conductive layer.

It is preferable that in the dye-sensitized solar cell electrode of the present invention, the catalyst layer is formed from platinum, and /or carbon.

The dye-sensitized solar cell of the present invention includes a working electrode; a counter electrode that is disposed to face the working electrode with a space therebetween; and an electrolyte that fills in between the working electrode and the counter electrode, and contains iodine, wherein the counter electrode is the above-described dye-sensitized solar cell electrode.

The dye-sensitized solar cell electrode of the present invention ensures flexibility and a lightweight, achieves mass production and cost reduction, and has excellent iodine resistance. Therefore, the substrate can be prevented from being dyed with iodine, iodine penetration of the substrate can be prevented, and decomposition of the substrate due to iodine can be suppressed.

Thus, the dye-sensitized solar cell in which the dye-sensitized solar cell electrode of the present invention is used as the electrode can be used in various fields as a solar cell that can achieve mass production and cost reduction, and at the same time, in the dye-sensitized solar cell of the present invention, poor appearance due to iodine in the electrolyte can be prevented, and further, a decrease in power generation efficiency caused by substrate decomposition due to iodine in the electrolyte and iodine penetration of the substrate can be prevented.

### BRIEF DESCRIPTION OF THE DRAWINGS

FIG. 1 shows a cross-sectional view of an embodiment of the dye-sensitized solar cell of the present invention (an embodiment in which a cathode-side substrate exposing from a cathode-side conductive layer is in contact with an electrolyte).

FIG. 2 shows a cross-sectional view of an embodiment of the dye-sensitized solar cell electrode of the present invention (an embodiment in which a counter electrode includes a cathode-side substrate, a cathode-side conductive layer, and a catalyst layer).

FIG. 3 shows a cross-sectional view of another embodiment of the dye-sensitized solar cell electrode of the present invention (an embodiment in which a counter electrode includes a cathode-side substrate and a cathode-side conductive layer).

FIG. 4 shows a cross-sectional view of another embodiment of the dye-sensitized solar cell of the present invention (an embodiment in which a cathode-side conductive layer is interposed between a cathode-side substrate and an electrolyte).

FIG. 5 shows a cross-sectional view of another embodiment of the dye-sensitized solar cell of the present invention (an embodiment in which a left-side portion of the upper face of a cathode-side substrate exposing from a catalyst layer is in contact with an electrolyte, and right side faces of the cathode-side conductive layer and the catalyst layer are in contact with a sealing layer).

FIG. 6 shows a cross-sectional view of another embodiment of the dye-sensitized solar cell of the present invention (an embodiment in which a left-side portion of the upper face of a cathode-side substrate exposing from a catalyst layer is in contact with an electrolyte, and a right side face of the catalyst layer is in contact with a sealing layer).

FIG. 7 shows a cross-sectional view of another embodiment of the dye-sensitized solar cell of the present invention (an embodiment in which anode-side conductive layers and cathode-side conductive layers are connected to current collecting wirings).

### DETAILED DESCRIPTION OF THE INVENTION

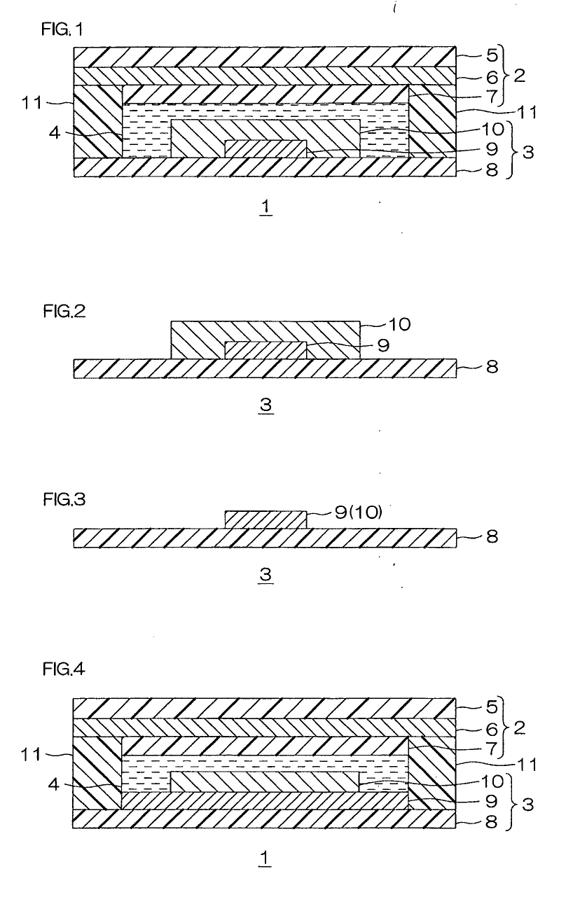

FIG. 1 shows a cross-sectional view of an embodiment of the dye-sensitized solar cell of the present invention (an embodiment in which a cathode-side substrate exposing from a cathode-side conductive layer is in contact with an electrolyte); and FIG. 2 shows a cross-sectional view of an embodiment of the dye-sensitized solar cell electrode of the present invention (an embodiment in which a counter electrode includes a cathode-side substrate, a cathode-side conductive layer, and a catalyst layer).

In FIG. 1, a dye-sensitized solar cell 1 includes a working electrode 2 (anode); a counter electrode (cathode, opposing electrode) 3 that is disposed to face the working electrode 2 in the thickness direction of the electrodes (up and down directions in FIG. 1) with a space therebetween; and an electrolyte 4 that fills in between the working electrode 2 and the counter electrode 3.

The working electrode 2 has a photosensitizing function, and is formed in a substantially flat plate shape. The working electrode 2 includes an anode-side substrate 5, an anode-side conductive layer 6 laminated below the anode-side substrate 5, and a dye-sensitized semiconductor layer 7 laminated below the anode-side conductive layer 6.

The anode-side substrate 5 is transparent, and is formed in a flat plate shape. For example, the anode-side substrate 5 is formed from an insulating plate or an insulating film including a rigid plate such as a glass substrate and a flexible film (excluding the flexible film composed of the liquid crystal polymer to be mentioned later) such as a plastic film.

Examples of the plastic material for the plastic film include polyester resins (excluding thermotropic liquid crystal polyester and thermotropic liquid crystal polyester amide to be mentioned later) such as polyethylene terephthalate (PET), polybutylene terephthalate, and polyethylene-2,6-naphthalate (PEN); acrylic resins such as polyacrylate and polymethacrylate; olefin resins such as polyethylene and polypropylene; vinyl resins such as polyvinyl chloride, an ethylene-vinyl acetate copolymer, and an ethylene-vinylalcohol copolymer; imide resins such as polyimide and polyamide-imide; and ether resins such as polyethernitrile and polyethersulfone. These plastic materials may be used alone, or may be used in combination of two or more.

The thickness of the anode-side substrate 5 is, for example, 5 to 500 μm, or preferably 10 to 400 μm.

The anode-side conductive layer 6 is composed of, for example, a transparent conductive thin film, and is formed below the entire lower face of the anode-side substrate 5.

Examples of the conductive materials that form the transparent conductive thin film include metal materials such as gold, silver, copper, platinum, nickel, tin, and aluminum; metal oxide (composite oxide) materials such as tin-doped indium oxide (ITO), fluorine-doped tin oxide (FTO), and zinc-doped indium oxide (IZO); and a carbon material such as carbon. These conductive materials may be used alone, or may be used in combination of two or more.

The resistivity of the anode-side conductive layer 6 is, for example, 1.0×10⁻²Ω·cm or less, or preferably 1.0×10⁻³Ω·cm or less.

The thickness of the anode-side conductive layer 6 is, for example, 0.01 to 100 μm, or preferably 0.1 to 10 μm.

The dye-sensitized semiconductor layer 7 is formed below the lower face and at a widthwise (the left and right directions in FIG. 1) middle portion of the anode-side conductive layer 6. That is, the dye-sensitized semiconductor layer 7 is formed so that both widthwise end portions of the anode-side conductive layer 6 are exposed.

The dye-sensitized semiconductor layer 7 is formed by laminating dye-sensitized semiconductor particles into a sheet. Such dye-sensitized semiconductor particles are, for example, porous semiconductor particles composed of metal oxide to which dye is adsorbed.

Examples of the metal oxide include titanium oxide, zinc oxide, tin oxide, tungsten oxide, zirconium oxide, hafnium oxide, strontium oxide, indium oxide, yttrium oxide, lanthanum oxide, vanadium oxide, niobium oxide, tantalum oxide, chromic oxide, molybdenum oxide, iron oxide, nickel oxide, and silver oxide. A preferable example is titanium oxide.

Examples of the dye include metal complexes such as a ruthenium complex and a cobalt complex; and organic dyes such as a cyanine dye, a merocyanine dye, a phthalocyanine dye, a coumarin dye, a riboflavin dye, a xanthene dye, a triphenylmethane dye, an azo dye, and a chinone dye. Preferable examples are a ruthenium complex and a merocyanine dye.

The average particle size of the dye-sensitized semiconductor particles is, on the primary particle size basis, for example, 5 to 200 nm, or preferably 8 to 100 nm.

The thickness of the dye-sensitized semiconductor layer 7 is, for example, 0.4 to 100 μm, preferably 0.5 to 50 μm, or more preferably 0.5 to 15 μm.

The counter electrode 3, which is to be described in detail later, is formed in a substantially flat plate shape.

The electrolyte 4 is prepared, for example, as a solution in which the electrolyte is dissolved in a solvent (liquid electrolyte), or as a gel electrolyte obtained by gelling such a solution.

The electrolyte 4 includes, as essential components, iodine, and/or a combination of iodine and an iodine compound (redox system).

Examples of the iodine compound include metal iodides such as lithium iodide (LiI), sodium iodide (NaI), potassium iodide (KI), cesium iodide (CsI), and calcium iodide (CaI₂); and organic quaternary ammonium iodide salts such as tetraalkyl ammonium iodide, imidazolium iodide, and pyridinium iodide.

The electrolyte 4 may also include, as optional components, for example, halogens (excluding iodine) such as bromine; or a combination of a halogen and a halogen compound (excluding a combination of iodine and an iodine compound) such as a combination of bromine and a bromine compound.

Examples of the solvent include organic solvents, and an aqueous solvent such as water. Examples of the organic solvents include carbonate compounds such as dimethyl carbonate, diethyl carbonate, methyl ethyl carbonate, ethylene carbonate, and propylene carbonate; ester compounds such as methyl acetate, methyl propionate, and gamma-butyrolactone; ether compounds such as diethylether, 1,2-dimethoxyethane, 1,3-dioxolane, tetrahydrofuran, and 2-methyl-tetrahydrofuran; heterocyclic compounds such as 3-methyl-2-oxazolidinone, and 2-methylpyrrolidone; nitrile compounds such as acetonitrile, methoxyacetonitrile, propionitrile, and 3-methoxypropionitrile; and aprotic polar compounds such as sulfolane, dimethyl sulfoxide, and dimethylformamide. A preferable example is an organic solvent, and more preferable example is a nitrite compound.

The proportion of the electrolyte content relative to 100 parts by weight of the liquid electrolyte is, for example, 0.001 to 10 parts by weight, or preferably 0.01 to 1 parts by weight. Although it depends on the molecular weight of the electrolyte, the electrolyte concentration in the electrolyte 4 may be set to, on the normality basis, for example, 0.001 to 10M, or preferably 0.01 to 1M.

The gel electrolyte is prepared by adding, for example, a known gelling agent at an appropriate ratio into a liquid electrolyte.

Examples of the gelling agent include a low molecular weight gelling agent such as a natural higher fatty acid, and polysaccharides such as amino acid compounds; and a high molecular weight gelling agent such as a fluorine-based polymer (e.g., polyvinylidene fluoride, a vinylidene fluoride-hexafluoropropylene copolymer, etc.), a vinyl-based polymer (e.g., polyvinyl acetate, polyvinyl alcohol, etc.).

The dye-sensitized solar cell 1 is also provided with a sealing layer 11 for sealing in the electrolyte 4 between the working electrode 2 and the counter electrode 3.

The sealing layer 11 fills in between the working electrode 2 and the counter electrode 3, at both widthwise end portions of the dye-sensitized solar cell 1. The sealing layer 11 is disposed adjacent to and at both outer side faces of the dye-sensitized semiconductor layer 7.

Examples of the sealing material that forms the sealing layer 11 include a silicone resin, an epoxy resin, a polyisobutylene-based resin, a hot-melt resin, and fritted glass.

The thickness of the sealing layer 11 (the length in the up or down direction) is, for example, 5 to 500 μm, preferably 5 to 100 μm, or more preferably 10 to 50 μm.

In the dye-sensitized solar cell 1 of FIG. 1, an embodiment of the dye-sensitized solar cell electrode of the present invention (FIG. 2) is used as the counter electrode 3, and the counter electrode 3 includes a cathode-side substrate 8 as the substrate.

In FIGS. 1 and 2, the cathode-side substrate 8 is formed from a flexible film (hereinafter, may be referred to as a liquid crystal polymer film), which is formed from a liquid crystal polymer.

Examples of the liquid crystal polymer include a thermotropic liquid crystal polyester and a thermotropic liquid crystal polyester amide that are synthesized by using compounds [1] to [4] shown below or derivatives thereof as raw materials.
[1] Aromatic or aliphatic dihydroxy compounds (typical examples are shown in the following formulas (4) to (10).)

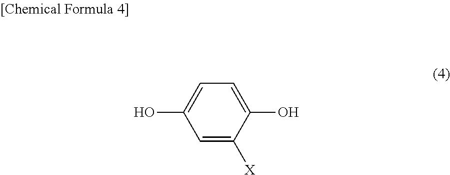

(in the formula (4), X represents an atom such as a hydrogen atom or a halogen atom; or a group such as a lower alkyl group or a phenyl group.)

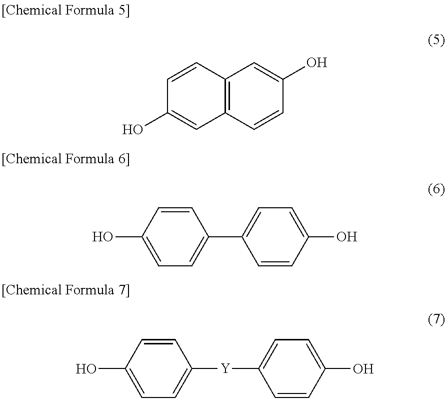

(in the formula (7), Y represents a group such as —O—, —CH₂—, or —S—.)

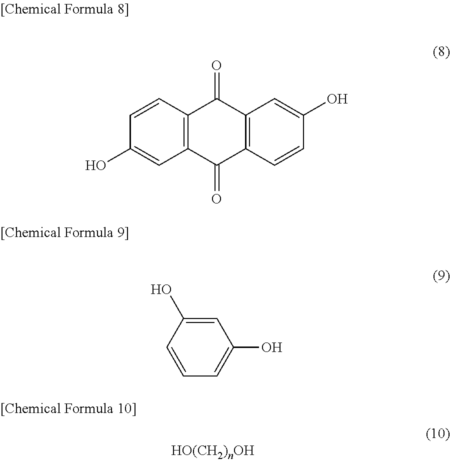

(in the formula (10), n represents an integer from 2 to 12.)
[2] Aromatic or aliphatic dicarboxylic acid (typical examples are shown in the following formulas (11) to (17).)

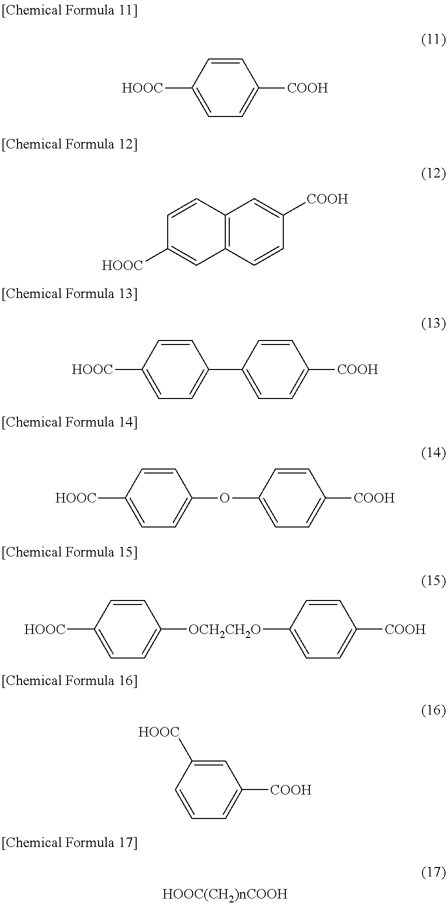

(in the formula (17), n represents an integer from 2 to 12.)
[3] Aromatic hydroxycarboxylic acid (typical examples are shown in the following formulas (18) to (21).)

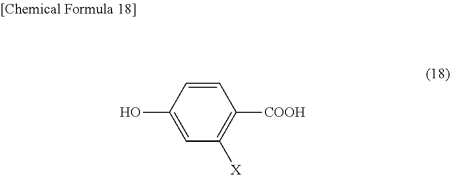

(in the formula (18), X represents an atom such as a hydrogen atom or a halogen atom; or a group such as a lower alkyl group or a phenyl group.)

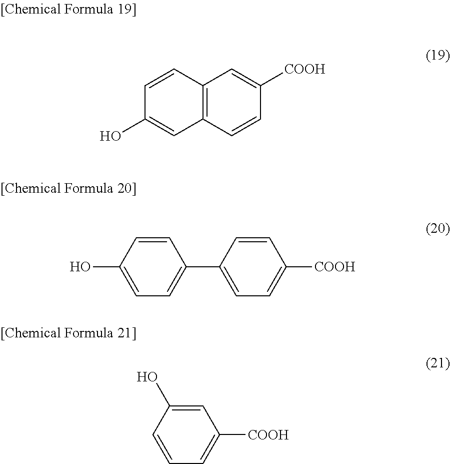

[4] Aromatic diamine, aromatic hydroxyamine or aromatic aminocarboxylic acid (typical examples are shown in the following formulas (22) to (24).)

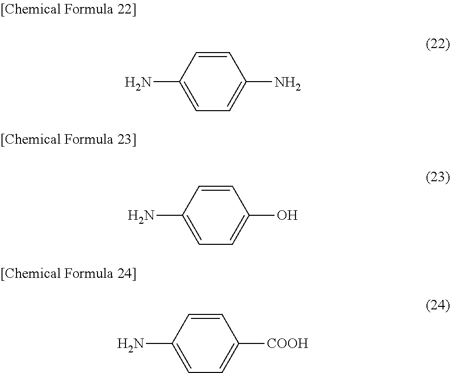

Examples of the liquid crystal polymer preferably include para-hydroxy benzoic acid ester-containing copolymers such as a copolymer (1) containing a unit a and a unit b represented by the following formula (1); a copolymer (2) containing a unit c to a unit e represented by the following formula (2); and a copolymer (3) containing a unit f and a unit g represented by the following formula (3).

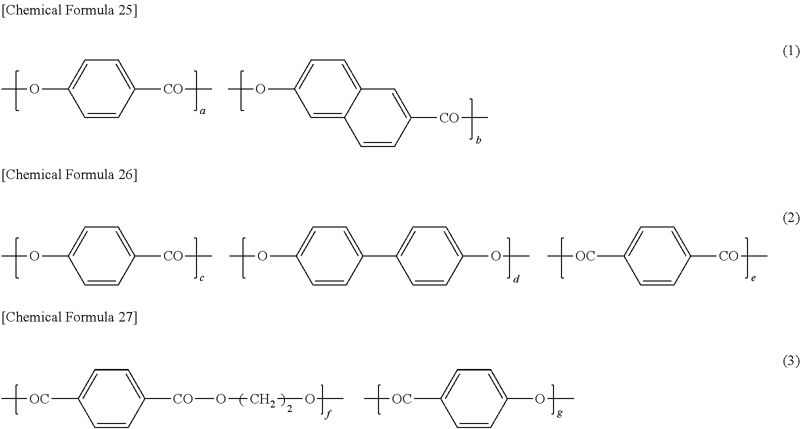

The copolymers (1) to (3) are all synthesized using, for example, a monomer including 50 to 80 mol % of para-hydroxy benzoic acid as a raw material.

To be specific, the copolymer (1) is a polycondensate of para-hydroxybenzoic acid and 2,6-hydroxynaphthoic acid, and preferably contains 50 to 80 mol % of the unit a and 20 to 50 mol % of the unit b.

The copolymer (2) is a polycondensate of para-hydroxybenzoic acid, 4,4′-dihydroxy-diphenyl, and terephthalic acid, and preferably contains 50 to 80 mol % of the unit c, 1 to 49 mol % of the unit d, and 1 to 49 mol % of the unit e.

The copolymer (3) is a polycondensate of para-hydroxybenzoic acid and ethylene glycol, and preferably contains 20 to 50 mol % of the unit f, and 50 to 80 mol % of the unit g.

The above-described copolymers (1) to (3) may be used alone, or may be used in combination.

More preferable example of the liquid crystal polymer is the copolymer (1).

As such a liquid crystal polymer film, commercially available ones may be used, including, for example, VECSTAR series (manufactured by Kuraray Co., Ltd.), and BIAC® series (manufactured by Japan Gore-Tex Inc.).

The weight average molecular weight of the liquid crystal polymer is, for example, 10000 to 150000, or preferably 20000 to 70000.

The melting point of the liquid crystal polymer is, for example, 250° C. or more, or preferably 280° C. or more, and generally 610° C. or less.

The water absorption (JIS C-6481, conditions: E-24/50+D-24/23) of the liquid crystal polymer film is, for example, 5% or less, preferably 1% or less, or more preferably 0.1% or less, and generally 0.001% or more.

The linear expansion coefficient (50 to 100° C.) of the liquid crystal polymer film is, for example, 100 ppm/° C. or less, or preferably 50 ppm/° C. or less, and generally 0.1 ppm/° C. or more.

The thickness of the cathode-side substrate 8 is, for example, 5 to 500 μm, preferably 8 to 100 μm, or more preferably 12 to 50 μm. When the thickness of the cathode-side substrate 8 is below the above-described range, workability may be reduced, and when the thickness of the cathode-side substrate 8 is above the above-described range, there may be a cost increase.

The counter electrode 3 further includes, to be specific, a cathode-side conductive layer 9 as the conductive layer, and a catalyst layer 10.

The cathode-side conductive layer 9 is formed on the cathode-side substrate 8. To be specific, the cathode-side conductive layer 9 is composed of a conductive thin film, and is formed at a widthwise middle portion (center portion) of the upper face of the cathode-side substrate 8. To be specific, the cathode-side conductive layer 9 is included in the dye-sensitized semiconductor layer 7 when projected in the thickness direction thereof, and is formed such that both widthwise end portions of the cathode-side substrate 8 are exposed.

Examples of the conductive material that forms the cathode-side conductive layer 9 include the conductive materials that are the same as the conductive materials that form the above-described anode-side conductive layer 6. Preferable examples are gold, silver, copper, platinum, nickel, tin, ITO, FTO, and carbon. Such conductive materials are advantageous in that electrons are efficiently given and received.

These conductive materials may be used alone, or may be used in combination of two or more.

The resistivity of the cathode-side conductive layer 9 is, for example, 1.0×10⁻²Ω·cm or less, preferably 1.0×10⁻³Ω·cm or less, or more preferably 1.0×10⁻⁵Ω·cm or less.

The thickness of the cathode-side conductive layer 9 is, for example, 0.1 to 100 μm, or preferably 1 to 50 μm. When the thickness of the cathode-side conductive layer 9 is below the above-described range, the conductivity may decrease excessively (the resistivity increases excessively), and when the thickness of the cathode-side conductive layer 9 is above the above-described range, costs may increase and it may become difficult to achieve a thin product.

The catalyst layer 10 is formed on the cathode-side conductive layer 9. To be specific, the catalyst layer 10 is formed on the cathode-side substrate 8 so as to cover the surface (upper face and both widthwise side faces) of the cathode-side conductive layer 9.

The catalyst layer 10 is included in the dye-sensitized semiconductor layer 7 when projected in the thickness direction thereof, and one widthwise side face of the catalyst layer 10 is positioned between one widthwise side face of the dye-sensitized semiconductor layer 7 and one widthwise side face of the cathode-side conductive layer 9. The other widthwise side face of the catalyst layer 10 is positioned between the other widthwise side face of the dye-sensitized semiconductor layer 7 and the other widthwise side face of the cathode-side conductive layer 9.

Examples of the material that forms the catalyst layer 10 include noble metal materials such as platinum, ruthenium, and rhodium; conductive organic materials such as polydioxythiophene and polypyrole; and a carbon material such as carbon. Preferable examples are platinum and carbon. Such materials are advantageous in that electrons are efficiently given and received.

These materials may be used alone, or may be used in combination of two or more.

The thickness of the catalyst layer 10 is, for example, 50 nm to 100 μm, or preferably 100 nm to 50 μm. When the thickness of the catalyst layer 10 is below the above-described range, in the electrolyte 4, acceleration of oxidation-reduction reaction by electrolyte may not be achieved sufficiently, and power generation efficiency may decrease. When the thickness of the catalyst layer 10 exceeds the above-described range, costs may increase.

To produce the dye-sensitized solar cell 1, first, the working electrode 2, the counter electrode 3, and the electrolyte 4 are prepared (or made).

The working electrode 2 is made by sequentially laminating the anode-side substrate 5, the anode-side conductive layer 6, and the dye-sensitized semiconductor layer 7 downward in the thickness direction.

The electrolyte 4 is prepared as the above-described liquid electrolyte or a gelled electrolyte.

To produce the counter electrode 3, first, the cathode-side substrate 8 is prepared.

Next, as necessary, a surface treatment is given to the upper face of the cathode-side substrate 8 by a plasma treatment or a physical vapor deposition method. Such surface treatments may be given singly or in combination of two or more.

Examples of the plasma treatment include a nitrogen plasma treatment. Conditions of the nitrogen plasma treatment are noted below.

Pressure (reduced pressure): 0.01 to 100 Pa, or preferably 0.05 to 10 Pa Flow rate of nitrogen introduced: 10 to 1000 SCCM (standard cc/min), or preferably 10 to 300 SCCM

Treatment temperature: 0 to 150° C., or preferably 0 to 120° C.

Electric power: 30 to 1800 W, or preferably 150 to 1200 W

Treatment time: 0.1 to 30 minutes, or preferably 0.15 to 10 minutes

The nitrogen plasma treatment causes the upper face of the cathode-side substrate 8 to be nitrogenized.

Examples of the physical vapor deposition method include vacuum deposition, ion plating, and sputtering. A preferable example is sputtering.

Examples of the sputtering include a metal sputtering using metals such as nickel or chromium as a target. By metal sputtering, a metal thin film (not shown) is formed on the upper face of the cathode-side substrate 8. The thickness of the metal thin film is, for example, 1 to 1000 nm, or preferably 10 to 500 nm.

The above-described surface treatment allows an improvement in adhesion of the cathode-side conductive layer 9 to the cathode-side substrate 8.

Next, the cathode-side conductive layer 9 is formed on the cathode-side substrate 8.

The cathode-side conductive layer 9 is formed, for example, by a printing method, a spraying method, a physical vapor deposition method, an additive method, or a subtractive method, into the above-described pattern.

In the printing method, for example, a paste containing microparticles of the above-described conductive material is screen printed on the upper face of the cathode-side substrate 8, into the above-described pattern.

In the spraying method, for example, a dispersion of the above-described conductive material microparticles dispersed in a known dispersion medium is prepared first. Also, a mask having a predetermined pattern of opening is used to cover the upper face of the cathode-side substrate 8. Afterwards, from above the cathode-side substrate 8 and the mask, the prepared dispersion is blown (sprayed). Afterwards, the mask is removed and the dispersion medium is evaporated.

As the physical vapor deposition method, sputtering is preferably used. To be specific, after covering the upper face of the cathode-side substrate 8 with a mask having a predetermined pattern of opening, sputtering is performed using, for example, metal materials or metal oxide materials as a target, and then the mask is removed.

In the additive method, for example, a thin conductive film (seed film), which is not shown, is formed first on the upper face of the cathode-side substrate 8. As the thin conductive film, a chromium thin film is laminated by sputtering, or preferably by chromium sputtering. When the metal thin film is already formed by the above-described surface treatment (physical vapor deposition method), the formation of the thin conductive film can also serve as a surface treatment for the cathode-side substrate 8.

Then, after forming a plating resist having a reverse pattern to the above-described pattern on the upper face of the thin conductive film, the cathode-side conductive layer 9 is formed on the upper face of the thin conductive film exposing from the plating resist by electrolytic plating. Afterwards, the plating resist and the portion of the thin conductive film where the plating resist was laminated are removed.

In the subtractive method, for example, a two-layer substrate (copper-clad two-layer substrate, etc.) in which a conductive foil composed of the above-described conductive material is laminated on the upper face of the cathode-side substrate 8 in advance is prepared first, and after a dry film resist is laminated on the conductive foil, the dry film resist is exposed to light and developed, so that an etching resist having the same pattern as that of the above-described cathode-side conductive layer 9 is formed. Afterwards, the conductive foil exposing from the etching resist is subjected to a chemical etching using an etching solution such as an aqueous solution of ferric chloride, and then the etching resist is removed.

For the preparation of the two-layer substrate, a conductive foil may be bonded to the upper face of the cathode-side substrate 8 by heat-fusing, or a known adhesive layer may he interposed between the cathode-side substrate 8 and the conductive foil.

Upon forming the cathode-side conductive layer 9 by the above-described subtractive method, a commercially available product may be used as the copper-clad two-layer substrate. For example, a liquid crystal polymer copper-clad laminate plate in which a copper foil is laminated on the upper face of the liquid crystal polymer film in advance, such as ESPANEX L series (standard type/P type, manufactured by Nippon Steel Chemical Co., Ltd.), or BIAC®-RF-Clad series (manufactured by Japan Gore-Tex Inc.) is used.

Then, the catalyst layer 10 is formed on the cathode-side substrate 8 so as to cover the cathode-side conductive layer 9.

The catalyst layer 10 is formed, for example, by a known method such as a printing method, a spraying method, or a physical vapor deposition method, into the above-described pattern. The printing method, the spraying method, and the physical vapor deposition method can be performed according to the above-described method.

Preferably, when the catalyst layer 10 is formed from a noble metal, a physical vapor deposition method (for example, vacuum deposition, sputtering, etc.) is used; and when the catalyst layer 10 is formed from a conductive organic compound or a carbon material, a printing method or a spraying method is used.

The counter electrode 3 is thus made.

The counter electrode 3 thus made has a weight change rate in the iodine resistance test in Example to be mentioned later of, for example, 10 wt % or less, preferably 5 wt % or less, or more preferably 1 wt % or less and usually 0.01 wt % or more.

Then, the working electrode 2 and the counter electrode 3 are disposed to face each other so that the dye-sensitized semiconductor layer 7 and the catalyst layer 10 are adjacent to each other, with a space for providing the sealing layer 11 therebetween. At the same time, the sealing layer 11 is provided on one widthwise side of the working electrode 2 and the counter electrode 3, and after pouring in the electrolyte 4 between the working electrode 2 and the counter electrode 3, the sealing layer 11 is further provided on the other widthwise side of the working electrode 2 and the counter electrode 3, thus sealing in the electrolyte 4.

Although not shown in the drawings, upon providing the sealing layer 11, the sealing layers 11 are provided also at both anteroposterior (direction perpendicular to the width direction and the thickness direction) sides so as to seal in the electrolyte 4.

The dye-sensitized solar cell 1 is thus made.

The dye-sensitized solar cell 1 thus obtained is capable of ensuring flexibility and a light weight, and achieving mass production and cost reduction, because the counter electrode 3 includes the cathode-side substrate 8 composed of the liquid crystal polymer film.

The cathode-side substrate 8 of the counter electrode 3 is also excellent in iodine resistance. Therefore, the cathode-side substrate 8 can be prevented from being dyed with iodine, and the cathode-side substrate 8 can also be prevented from being penetrated by iodine, and at the same time, decomposition of the cathode-side substrate 8 by iodine can be suppressed.

Thus, the dye-sensitized solar cell 1 in which the above-described counter electrode 3 is used can be used in various fields as a solar cell that achieves mass production and low-cost, and at the same time, poor appearance due to iodine of the electrolyte 4 can be prevented, and further a decrease in power generation efficiency due to decomposition or penetration of the cathode-side substrate 8 by iodine of the electrolyte 4 can be prevented.

In the above description, among the substrates (anode-side substrate 5 and cathode-side substrate 8) of the working electrode 2 and the counter electrode 3 in the dye-sensitized solar cell 1, only the substrate of the cathode-side substrate 8 is formed from the liquid crystal polymer film. However, for example, both of the anode-side substrate 5 and the cathode-side substrate 8 may be formed from the liquid crystal polymer film.

It is also possible to form the anode-side substrate 5 from the liquid crystal polymer film, while forming the cathode-side substrate 8 from the above-described glass substrate or a plastic film.

Preferably, at least the cathode-side substrate 8 is formed from the liquid crystal polymer film. That is, preferable embodiments are an embodiment in which both of the cathode-side substrate 8 and the anode-side substrate 5 are formed from the liquid crystal polymer film; and an embodiment in which the cathode-side substrate 8 is formed from the liquid crystal polymer film, and the anode-side substrate 5 is formed from a glass substrate or a plastic film.

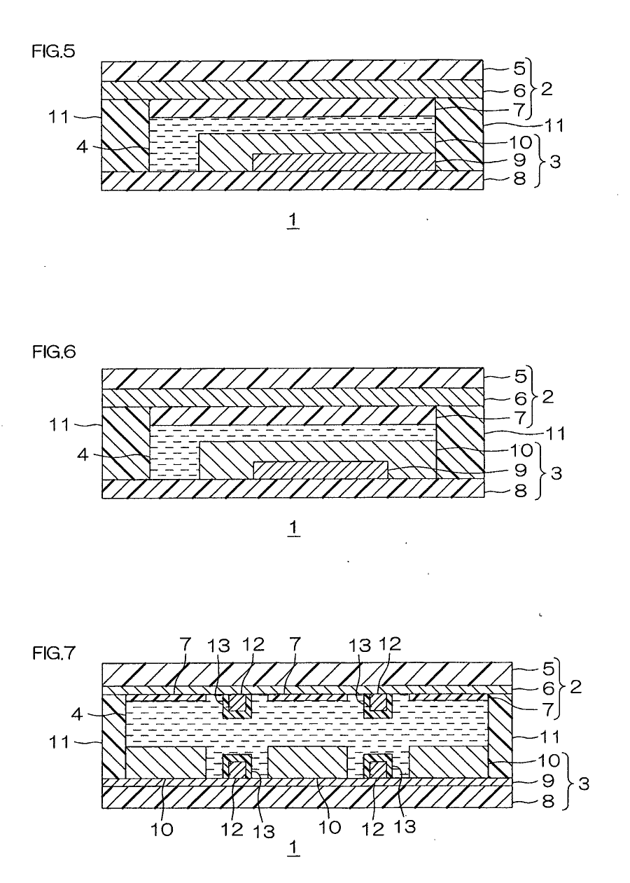

FIG. 3 shows a cross-sectional view of another embodiment of the dye-sensitized solar cell electrode of the present invention (an embodiment in which the counter electrode includes the cathode-side substrate and the cathode-side conductive layer). FIGS. 4 to 7 show cross-sectional views of other embodiments of the dye-sensitized solar cell of the present invention. FIG. 4 shows an embodiment in which the cathode-side conductive layer is interposed between the cathode-side substrate and the electrolyte; FIG. 5 shows an embodiment in which a left-side portion of the upper face of the cathode-side substrate exposing from the catalyst layer is in contact with the electrolyte, and the right side faces of the cathode-side conductive layer and the catalyst layer are in contact with the sealing layer; FIG. 6 shows an embodiment in which a left-side portion of the upper face of the cathode-side substrate exposing from the catalyst layer is in contact with the electrolyte, and the right side face of the catalyst layer is in contact with the sealing layer; and FIG. 7 shows an embodiment in which the anode-side conductive layer and the cathode-side conductive layer are connected to current collecting wirings.

In the following figures, the members corresponding to the components mentioned above are designated by the same reference numerals, and detailed descriptions thereof are omitted.

Although the catalyst layer 10 is provided in the dye-sensitized solar cell electrode 3 in the above description, for example, as shown in FIG. 3, the dye-sensitized solar cell electrode 3 may be formed from the cathode-side substrate 8 and the cathode-side conductive layer 9, without using the catalyst layer 10.

The cathode-side conductive layer 9 may also serve as the catalyst layer 10. In such a case, the cathode-side conductive layer 9 is preferably formed from a carbon material such as carbon.

Although the portion of the upper face of the cathode-side substrate 8 exposing from the cathode-side conductive layer 9, the catalyst layer 10, and the sealing layer 11 is in contact with the electrolyte 4 in the above description, for example, as shown in FIG. 4, by forming the cathode-side conductive layer 9 so as to bring both widthwise side faces of the cathode-side conductive layer 9 into contact with inner side faces of the sealing layer 11, the entirety of the upper face of the cathode-side substrate 8 can be covered with the cathode-side conductive layer 9 and the sealing layer 11.

In FIG. 4, the cathode-side conductive layer 9 is formed, so as to extend between the sealing layers 11 in the widthwise direction. That is, when the cathode-side conductive layer 9 is projected in the thickness direction thereof, position of the both widthwise side faces thereof coincides with the position of the both widthwise side faces of the dye-sensitized semiconductor layer 7. That is, the cathode-side conductive layer 9 is interposed between the cathode-side substrate 8, and the electrolyte 4 and catalyst layer 10.

The catalyst layer 10 is formed at a widthwise middle portion (center portion) of the upper face of the cathode-side conductive layer 9. That is, both widthwise end portions of the upper face of the cathode-side conductive layer 9 is exposed from the catalyst layer 10.

In the dye-sensitized solar cell 1, because the cathode-side conductive layer 9 is interposed between the cathode-side substrate 8 and the electrolyte 4, the electrolyte 4 does not directly contact the cathode-side substrate 8, and therefore direct penetration of the cathode-side substrate 8 by iodine in the electrolyte 4 can be prevented.

However, when the cathode-side conductive layer 9 is formed from, for example, ITO, iodine in the electrolyte 4 may penetrate the cathode-side conductive layer 9 and reach the cathode-side substrate 8. In such a case as well, because the cathode-side substrate 8 in the counter electrode 3 of the dye-sensitized solar cell 1 is excellent in iodine resistance, the cathode-side substrate 8 can be effectively prevented from being dyed with iodine, and the cathode-side substrate 8 can also be effectively prevented from being penetrated by iodine, and at the same time, decomposition of the cathode-side substrate 8 by iodine can be effectively suppressed.

It is also possible, as shown in FIG. 5, to form the cathode-side conductive layer 9 and the catalyst layer 10 so as to bring one widthwise side (right) faces of the cathode-side conductive layer 9 and the catalyst layer 10 in contact with the inside (left) face of the one (right) widthwise side of the sealing layer 11.

Furthermore, as shown in FIG. 6, it is also possible to form the catalyst layer 10 so that the one widthwise side (right) face of the catalyst layer 10 is brought in contact with the inside (left) face of the one (right) widthwise side of the sealing layer 11.

Furthermore, as shown in FIG. 7, it is also possible to provide a plurality of dye-sensitized semiconductor layers 7 and a plurality of catalyst layers 10 along the width direction thereof, together with current collecting wirings 12 between the plurality of dye-sensitized semiconductor layers 7 and between the plurality of catalyst layers 10.

Each of the plurality of dye-sensitized semiconductor layers 7 and each of the plurality of catalyst layers 10 are aligned in the width direction thereof with a space therebetween, and are at matching positions when the each of the plurality of dye-sensitized semiconductor layers 7 and the each of the plurality of catalyst layers 10 are projected in the thickness direction thereof.

In the working electrode 2, the plurality of current collecting wirings 12 are formed between the each of the plurality of dye-sensitized semiconductor layers 7 at the lower face of the anode-side conductive layer 6, and each of the plurality of current collecting wirings 12 is disposed in the width direction thereof with a space between the each of the plurality of current collecting wirings 12 and the each of the plurality of dye-sensitized semiconductor layers 7. The current collecting wirings 12 in the working electrode 2 are electrically connected to the anode-side conductive layer 6.

In the counter electrode 3, the plurality of current collecting wirings 12 are formed between the each of the catalyst layers 10 on the upper face of the cathode-side conductive layer 9, and the each of the current collecting wirings 12 is disposed in the width direction thereof with a space between the each of the catalyst layers 10. The current collecting wirings 12 in the counter electrode 3 are electrically connected to the cathode-side conductive layer 9.

As conductive materials for forming the current collecting wirings 12, the conductive materials same as those described above may be used. The thickness of the current collecting wirings 12 is, for example, 0.5 to 50 μm, or preferably 0.5 to 20 μm.

On the surface of the current collecting wirings 12, a protection layer 13 is formed for preventing corrosion of the current collecting wirings 12 by the electrolyte 4.

Examples of the material for forming the protection layer 13 include resin materials such as epoxy resin and acrylic resin, and metal materials such as nickel and gold. The thickness of the protection layer 13 is, for example, 0.5 to 30 μm.

In such dye-sensitized solar cells 1, power generation efficiency can be improved by collecting electric currents of the plurality of anode-side conductive layers 6 and of the cathode-side conductive layers 9 with the plurality of current collecting wirings 12.

### Examples

### Example 1

A cathode-side substrate composed of a liquid crystal polymer film (VECSTAR, thickness 25 μm, manufactured by Kuraray Co., Ltd.) was prepared (ref. FIG. 2). The liquid crystal polymer film has a melting point of 295° C., a water absorption (JIS C-6481, conditions: E-24/50+D-24/23) of 0.04%, and a linear expansion coefficient (50 to 100° C.) of 17 ppm/° C.

Then, the upper face of the cathode-side substrate was subjected to a nitriding treatment by a nitrogen plasma treatment. Conditions for the nitrogen plasma treatment are noted below.

Pressure (reduced pressure): 1.2 Pa

Flow rate of nitrogen introduced: 70 SCCM

Treatment Temperature: 21° C.

Electric Power: 200 W

Treatment Time: 0.5 minutes

Then, a cathode-side conductive layer composed of copper was formed into the above-described pattern by an additive method (ref. FIG. 2).

That is, a thin conductive film composed of a chromium thin film having a thickness of 100 nm was formed first on the upper face of the cathode-side substrate by chromium sputtering. Then, after a plating resist was formed on the upper face of the thin conductive film in a pattern reverse to the above-described pattern, a cathode-side conductive layer having a thickness of 18 was formed on the surface of the thin conductive film exposing from the plating resist by electrolytic copper plating. Afterwards, the plating resist and the portion of the thin conductive film where the plating resist was laminated were removed. The cathode-side conductive layer

Afterwards, a catalyst layer composed of platinum was formed on the cathode-side substrate in a pattern covering the surface of the cathode-side conductive layer.

That is, after covering the upper face of the cathode-side substrate and the cathode-side conductive layer with a mask having the above-described predetermined pattern of openings first, a catalyst layer having a thickness of 300 nm was formed by platinum vacuum deposition (ref. FIG. 2). Afterwards, the mask was removed.

The counter electrode (dye-sensitized solar cell electrode) shown in FIG. 2 was thus made.

### Comparative Example 1

A counter electrode (dye-sensitized solar cell electrode) was made in the same manner as in Example 1, except that a polyimide film (APICAL NPI, thickness 25 μm, manufactured by Kaneka Corporation) was used instead of the liquid crystal polymer film (VECSTAR, thickness 25 μm, manufactured by Kuraray Co., Ltd.) in the preparation of the cathode-side substrate.

The above-described polyimide film has a water absorption (JIS C-6481, conditions: E-24/50+D-24/23) of 1.7%, and a linear expansion coefficient (50 to 100° C.) of 18 ppm/° C.

### Comparative Example 2

A counter electrode (dye-sensitized solar cell electrode) was made in the same manner as in Example 1, except that a polyethylene naphthalate film (Teonex Q51, PEN film, thickness 25 μm, manufactured by Teijin DuPont Films Japan Limited) was used instead of the liquid crystal polymer film (VECSTAR, thickness 25 μm, manufactured by Kuraray Co., Ltd.) in the preparation of the cathode-side substrate.

The above-described polyethylene naphthalate film has a water absorption (JIS C-6481, conditions: E-24/50+D-24/23) of 0.3%, and a linear expansion coefficient (50 to 100° C.) of 13 ppm/° C.

### (Evaluation)

### (Iodine Resistance Test)

The dye-sensitized solar cell electrodes obtained in Example and Comparative Examples were immersed in a liquid electrolyte (electrolyte: iodine, normality: 0.1 M, solvent: 3-methoxypropionitrile), and allowed to stand at 80° C. for one week.

### 1) Weight Change Rate

The weight change rate (reduction rate, wt %) of the dye-sensitized solar cell electrode before and after the above-described iodine resistance test was measured. The results are shown in Table 1.

### 2) Storage Modulus

The storage modulus at a temperature of 100° C. of the cathode-side substrate of the dye-sensitized solar cell electrode was measured before and after the above-described iodine resistance test using a viscoelasticity measuring instrument (RSA-3, manufactured by TA Instruments). The results are shown in Table 1.

### 3) Glass Transition Temperature

The glass transition temperature of the dye-sensitized solar cell electrode was measured before and after the above-described iodine resistance test.

However, no glass transition occurred in Example 1.

In Comparative Example 2, it was found that the glass transition temperature decreased by 25° C. due to the iodine resistance test.

On the other hand, in Comparative Example 1, almost no change of the glass transition temperature was found before and after the iodine resistance test.

### 4) Appearance

Presence or absence of dyeing of the cathode-side substrate of the dye-sensitized solar cell electrode before and after the above-described iodine resistance test was checked visually. The results are shown in Table 1. Details of the abbreviations in Table 1 are noted below. NO: It was confirmed that the cathode-side substrate was not dyed with iodine. YES: It was confirmed that the cathode-side substrate was dyed with iodine.

TABLE 1

| | | Iodine Resistance Test | | | | | |
|---|---|---|---|---|---|---|---|
| | | Weight change | Storage Modulus | | Glass transition | | |
| Example • | Cathode-side | rate | (100° C.) | | temperature (° C.) | | |
| Comparative | substrate | [Reduction | Before | After | Before | After | Changes in |
| Example | Material | Rate](wt %) | Immersion | Immersion | Immersion | Immersion | Appearance |
| Example 1 | Liquid crystal | 0.3 | 1.8 × 10⁹ | 1.8 × 10⁹ | (No glass transition) | | NO |
| | polymer | | | | | | |
| Comparative | Polyimide | 14.8 | 3.4 × 10⁹ | 3.4 × 10⁹ | 410 | 410 | YES |
| Example 1 | | | | | | | |
| Comparative | Polyethylene | 2.5 | 3.9 × 10⁹ | 2.1 × 10⁹ | 150 | 125 | YES |
| Example 2 | naphthalate | | | | | | |

While the illustrative embodiments of the present invention are provided in the above description, such is for illustrative purpose only and it is not to be construed as limiting the scope of this invention. Modification and variation of the present invention that will be obvious to those skilled in the art is to be covered by the following claims.

What is claimed is:

1. A dye-sensitized solar cell electrode including a substrate comprising a flexible film formed from a liquid crystal polymer.

2. The dye-sensitized solar cell electrode according to claim 1, wherein the liquid crystal polymer is at least one para-hydroxybenzoic acid ester-containing copolymer selected from the group consisting of a copolymer containing a unit a and a unit b represented by the following formula (1); a copolymer containing a unit c to a unit e represented by the following formula (2); and a copolymer containing a unit f and a unit g represented by the following formula (3).

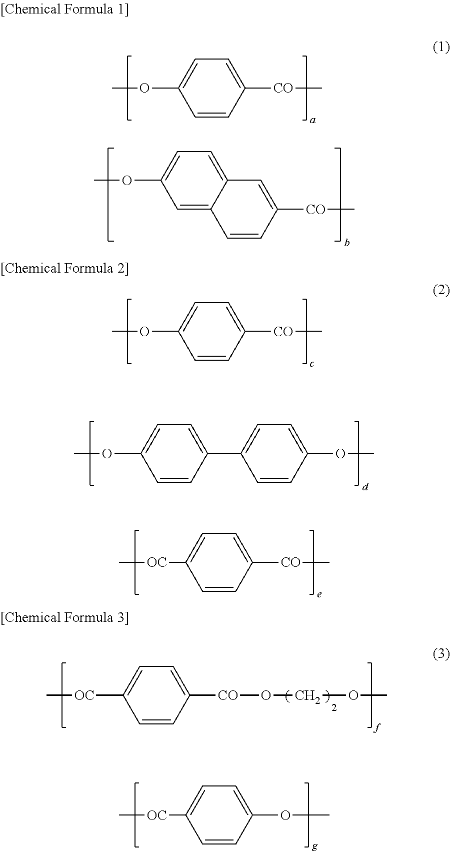

3. The dye-sensitized solar cell electrode according to claim 1, further comprising a conductive layer formed on the substrate.

4. The dye-sensitized solar cell electrode according to claim 3, wherein the conductive layer is formed from at least one selected from the group consisting of gold, silver, copper, platinum, nickel, tin, tin doped indium oxide, fluorine-doped tin oxide, and carbon.

5. The dye-sensitized solar cell electrode according to claim 3, wherein the conductive layer also serves as a catalyst layer.

6. The dye-sensitized solar cell electrode according to claim 5, wherein the conductive layer is formed from carbon.

7. The dye-sensitized solar cell electrode according to claim 3, further comprising a catalyst layer formed on the conductive layer.

8. The dye-sensitized solar cell electrode according to claim 7, wherein the catalyst layer is formed from platinum and/or carbon.

9. A dye-sensitized solar cell comprising:
a working electrode,
a counter electrode that is disposed to face the working electrode with a space therebetween, and
an electrolyte that fills in between the working electrode and the counter electrode, and contains iodine,
wherein the counter electrode is a dye-sensitized solar cell electrode including a substrate comprising a flexible film formed from a liquid crystal polymer.
